(19) United States
(12) Patent Application Publication
(10) Pub. No.: US 2011/0141693 A1
(43) Pub. Date: Jun. 16, 2011

(54) COOLING DEVICE

(76) Inventors: Patrick A. Walsh, County Limerick (IE); Ronan Grimes, County Tipperary (IE); Jeff Punch, County Limerick (IE)

(21) Appl. No.: 12/737,690

(22) PCT Filed: Aug. 10, 2009
(86) PCT No.: PCT/IE2009/000057

§ 371 Date: Feb. 7, 2011

(30) Foreign Application Priority Data
Aug. 8, 2008 (IE) 2008/0658
Jan. 30, 2009 (IE) 2009/0090

(51) Int. Cl. H05K 7/20; F28F 13/00; F28D 15/04

(52) U.S. Cl. 361/702; 165/121; 165/104.26

(57) ABSTRACT

A cooling device has a finless heat sink (1) which is rectangular in plan, having two spaced-apart plates (5, 6). A fan impeller (2) and motor (3) are supported between the plates (5, 6) for axial air flow in (7) and radial flow out. The device is placed on an electronic component (4) to be cooled. The component (4) may be an electronic package, for example. The heat sink (1) is manufactured from a single piece of conducting material. There is a rotor support (8) on the top plate (5), supporting a fan rotor (3). The rotor support (8) is in a device inlet for axial flow into the fan impeller (2). There are two opposed side walls (9) interconnecting the plates 5 and 6. The device outlet is the gap between the plates (5, 6) along the open sides. The cooling device is very efficient, compact, and inexpensive to manufacture.

### INTRODUCTION

The invention relates to cooling of items such as electronic devices.

Work performed in thermal management of electronics indicates that heat dissipation from medium to high power devices (10-150 W) is a key requirement for the electronics industry. This industry demands devices which are easy to implement, cost-competitive to manufacture, and which have a low profile. In larger scale electronic systems, Moore's law (Moore, 1965) causes the heat flux of many devices to double every 18 months, thus threatening component reliability. As a result there is a need for innovative cooling solutions, as conventional air based cooling techniques will no longer be sufficient in many cases. The primary barriers to be overcome in the implementation of such technologies are the development of cost competitive and easy to integrate solutions.

One problem within the industry is the need to develop solutions for low profile products such as notebook and laptop applications, along with the use of heat sink solutions within the slots of PC's and servers. In PC's many cooling solutions require two and greater slot solutions to cool in excess of 25 Watts from a standard GPU or CPU. At present, active cooling involves use of a fan and a finned heat sink to achieve the required performance. The use of fins increases cost, weight, reliability through fouling, and profile in many cases, which results in difficulties to implement in many emerging technologies.

U.S. Pat. No. 7,455,504 describes a fluid mover which can be used for cooling electronic components. It has a rotor in a number of parts, aimed to achieve laminar flow circumferentially around the rotor.

The invention is directed towards providing a cooling device which is more compact, and/or simpler to manufacture, and/or more efficient than existing cooling devices for operation in confined spaces such as electronic component cooling.

### SUMMARY

According to the invention there is provided a cooling device comprising:—
a fluid pump having a cooling device inlet;
a heat sink comprising axially spaced-apart opposed heat transfer surfaces and a side wall means connecting the surfaces; and
the heat sink having a cooling device outlet on a side thereof.

In one embodiment, the side wall means does not extend fully around the perimeter of the heat sink.

In one embodiment, the heat sink comprises a plurality of sides and the cooling device outlet is provided on at least one of the sides.

In one embodiment, the heat sink comprises four sides and the cooling device outlet is provided on at least one of the sides.

In one embodiment, the cooling device outlet is provided on one side, and side wall means are provided on the other three sides.

In one embodiment, the cooling device outlet is provided on two opposite sides and side walls are provided on the other two sides.

In one embodiment, the heat sink is approximately square-shaped in plan view.

In one embodiment, the spaced-apart opposed surfaces of the heat sink define a volume without heat dissipating fins extending from the heat sink inlet facing the pump.

In one embodiment, the cooling device outlet is on a side opposed to the heat sink inlet in the radial direction.

In one embodiment, the surfaces are substantially parallel, and the fluid pump comprises rotor impellers having a diameter in the range of 0.7 to 0.8 times width of the heat sink.

In one embodiment, the heat sink comprises at least two plates which are interconnected by the side wall means.

In one embodiment, a plate has an aperture providing the cooling device inlet.

In one embodiment, both plates comprise a heat conducting material.

In one embodiment, the heat sink comprises a single piece of material.

In one embodiment, the material is shaped to provide the heat sink.

In one embodiment, the heat sink is of moulded construction.

In one embodiment, the heat sink comprises an extrusion.

In one embodiment, the heat sink is formed by folding.

In one embodiment, the heat sink is generally U-shaped in transverse cross section.

In one embodiment, only a single plate comprises a heat conducting material.

In one embodiment, the device further comprises heat spreading means.

In one embodiment, the heat spreading means comprises heat pipe means.

In one embodiment, the heat pipe means is flattened to provide enhanced heat transfer between the pipe and a heat transfer surface of the heat sink.

In one embodiment, the gap between opposed surfaces of the heat sink is less than 5 mm.

In another aspect, the invention provides a cooling device comprising:—
a heat sink comprising a single plate having a heat conducting surface, the heat conducting surface being in contact with an article to be cooled or separated therefrom by a thermal interface material; and
a fluid pump adjacent to the conducting surface.

In another aspect, the invention provides a cooling device comprising:—
a fluid pump having a cooling device inlet;
a heat sink comprising axially spaced-apart opposed surfaces;
the heat sink having a cooling device outlet on a side thereof, wherein the heat sink comprises both heat conducting and non heat conducting materials.

In one embodiment, the heat sink comprises at least two plates which are spaced-apart in the axial direction, at least one of the plates being at least partially of a non heat-conducting material.

In one embodiment, the fluid pump extends through a plate.

In one embodiment, the fluid pump extends through both plates.

In one embodiment, the fluid pump protrudes from an external surface of at least one plate.

In one embodiment, the fluid pump is located offset with respect to the centre of the plates as viewed in plan, providing a contact area to a side of the pump for contact with a device to be cooled.

In a further aspect, the invention provides a cooling device comprising:—
a fluid pump having a cooling device inlet; and
a heat sink comprising axially spaced-apart opposed surfaces wherein the gap between the opposed surfaces of the heat sink is less than 5 mm.

In a still further aspect, the invention provides a heat sink for a cooling device as defined in any embodiment above.

In another aspect, the invention provides an electronic circuit assembly comprising a cooling device as defined above in any embodiment, and an electronic circuit in contact with the cooling device.

In one embodiment, the fluid pump comprises impeller blades and the circuit contacts the cooling device at a location aligned with the blades of the pump and a volume immediately radially beyond the blades.

In one embodiment, the location is adjacent to a side wall interconnecting the surfaces.

In a further aspect, the invention provides an electronic heat dissipating device comprising an electrical circuit assembly as defined above in any embodiment. In one embodiment, the heat dissipating device is portable.

### DESCRIPTION

### BRIEF DESCRIPTION OF THE DRAWINGS

The invention will be more clearly understood from the following description thereof given by way of example only with reference to the accompanying drawings, in which:—

FIG. 1 is an exploded isometric view of a cooling device according to one embodiment of the invention;

FIG. 2 is an isometric view of a cooling device according to another embodiment of the invention;

FIGS. 3, 4 and 5 are respectively front, plan, and end views of the device of FIG. 2 without a fan in place;

FIGS. 6 and 7 are respectively plan and front views of a plate used to form the cooling device of FIGS. 2 to 5;

FIG. 8 is an isometric view of the assembled cooling device according to the embodiment of the invention shown in FIG. 1;

FIGS. 9, 10 and 11 are respectively front, plan, and end views of the device of FIG. 8 without a fan in place;

FIGS. 12 and 13 are respectively plan and front views of a plate used to form the cooling device of FIGS. 8 to 11;

FIG. 14 is an isometric view of a cooling device similar to FIG. 8 in which one side is blocked;

FIG. 15 is an isometric view of a cooling device similar to FIG. 14 with two sides blocked;

FIG. 16 is an isometric view of a cooling device, similar to FIG. 14 with three sides blocked;

FIGS. 17 and 18 are isometric views of another cooling device in which the surface labelled 20 is not in direct thermal contact with a component to be cooled, it can be manufactured from a non-thermally conducting material;

FIGS. 19 and 20 are respectively isometric and side views of a further cooling device in operation in a confined space between nearby walls;

FIGS. 21 and 22 are respectively isometric and end views of a heat sink embodiment that can be extruded to form the cooling device of the invention;

FIGS. 23 and 24 are respectively isometric and end views of another heat sink embodiment that can formed by extrusion;

FIGS. 25 and 26 are respectively isometric and end views of a further heat sink that can be formed by extrusion;

FIG. 27 is an exploded isometric view of a cooling device having an extruded heat sink similar to that of FIGS. 21 and 22;

FIGS. 28 and 29 are top and bottom isometric views of the cooling device of FIG. 27 in use for cooling a microprocessor in contact with an external surface of the heat sink;

FIGS. 30, 31 and 32 are respectively isometric views from above and below and an end view of a cooling device of the invention with heat pipes for heat spreading;

FIGS. 33 to 37 are respectively isometric views from above and below, a plan view, an end view, and a side view of a cooling device with heat pipes for heat spreading;

FIGS. 38 and 39 are isometric views from above and below of another cooling device with heat pipes for heat spreading;

FIGS. 40 and 41 are isometric views from above and below of an inverted cooling device, in which the component to be cooled is in contact with a surface at the fan inlet side of the heat sink;

FIGS. 42 and 43 are respectively isometric and end views showing use of the inverted cooling device of FIGS. 40 and 41, in a confined space between two parallel walls;

FIG. 44 is an exploded isometric view of another cooling device using flattened heat pipes and two separate plates, and FIG. 45 is an isometric view of the assembled cooling device of FIG. 44, heat pipes connect cooling device to heat source;

FIGS. 46 and 47 are images showing measurements from a heat sink of the invention when vortices are steady between the upper and lower plates, the FIG. 46 images showing time averaged velocity vectors, the FIG. 47 images showing streamlines of flow field with vertical impingements on upper and lower surfaces;

FIG. 48 is a graph showing local heat transfer coefficient calculated from infra-red thermal maps shown on the right for the upper and lower surface;

FIGS. 49 to 51 are bar charts showing the results of power dissipation achieved for a 50 degree Kelvin temperature rise for different cooling devices;

FIG. 52 is a plot which illustrates the effect of placing a cooling device of the invention in close proximity to a wall and the variation of blocking different sides of a cooling device;

FIG. 53 is a plot showing thermal resistance of the upper and lower plates separately;

FIG. 54 is a plot showing the effect of making an upper plate from a non-conducting material;

FIG. 55 is a plot showing the effect of having the lower plate manufactured from a conducting material and only a portion of the upper surface manufactured from a conducting material;

FIG. 56 is a set of views showing another embodiment of the cooling device of the invention showing a fan positioned away from heat sink centreline;

FIG. 57 is a set of plots illustrating performance of the device of FIG. 56.

### DESCRIPTION OF THE EMBODIMENTS

In some embodiments a cooling device has a finless heat sink, which may be made from a single piece of material which is mechanically formed into the heat sink shape. This arrangement is cheaper to manufacture and implement in many devices. It can also be readily integrated with heat spreading technologies. The single piece of material, may be Al, Cu or other malleable material. A flat piece of material can be stamped and folded into shape to form a finless heat sink allowing cost-competitive manufacturing.

Alternatively, the heat sink may comprise several pieces of material, for example when integrated with heat spreading technologies.

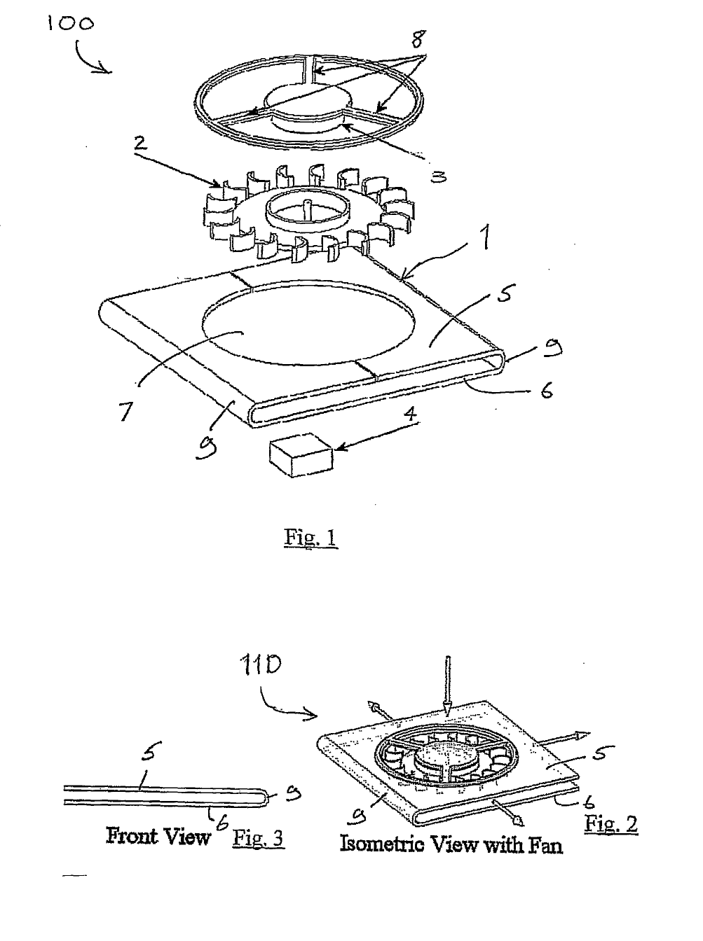

Referring to the drawings and initially to FIG. 1 a cooling device comprises a finless heat sink 1, a fan impeller 2, and a motor 3. The device is placed on an electronic component 4 to be cooled. The component 4 may be an electronic package, for example. The heat sink 1 is manufactured from a single piece of conducting material and is finless.

For clarity, the components in the drawings are not to scale. The heat sink 1 comprises a top plate 5, a bottom plate 6, and an axial flow inlet 7 in the top plate 5. There are side wall means which in this case is provided by two opposed side walls 9. The device outlet is the gap between the plates 5 and 6 along the open sides. There is a rotor support 8 on the top plate 5, supporting a fan rotor 3. The rotor support 8 is in a device inlet for axial flow into the fan impeller 2.

We have found that the diameter of the rotor of the fan should be approximately 0.7-0.8 times the shorter length scale of the heat sink as viewed in plan.

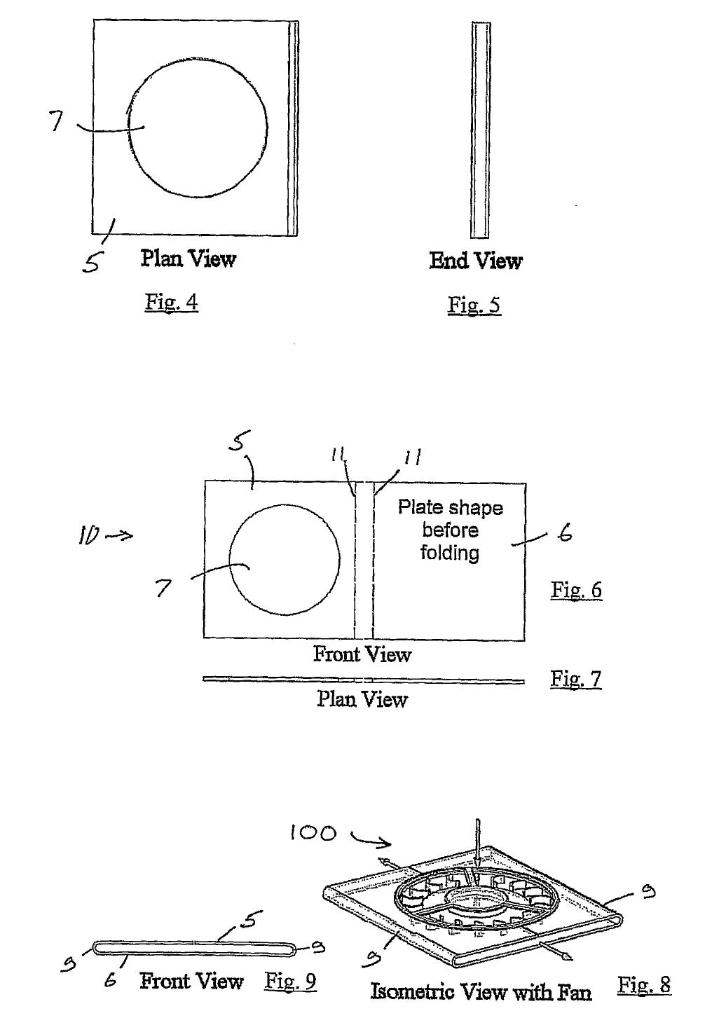

FIGS. 2 to 7 illustrate manufacture of a cooling device 110 having a finless heat sink which is formed from a single sheet 10 which is folded along fold lines which are illustrated as dashed lines 11. The arrows in FIG. 2 represent the direction of airflow when in operation. In this case there is only a single side wall 9 and the flow can exit through 75% of the possible exit area. FIGS. 6 and 7 illustrate a plate 10 before forming.

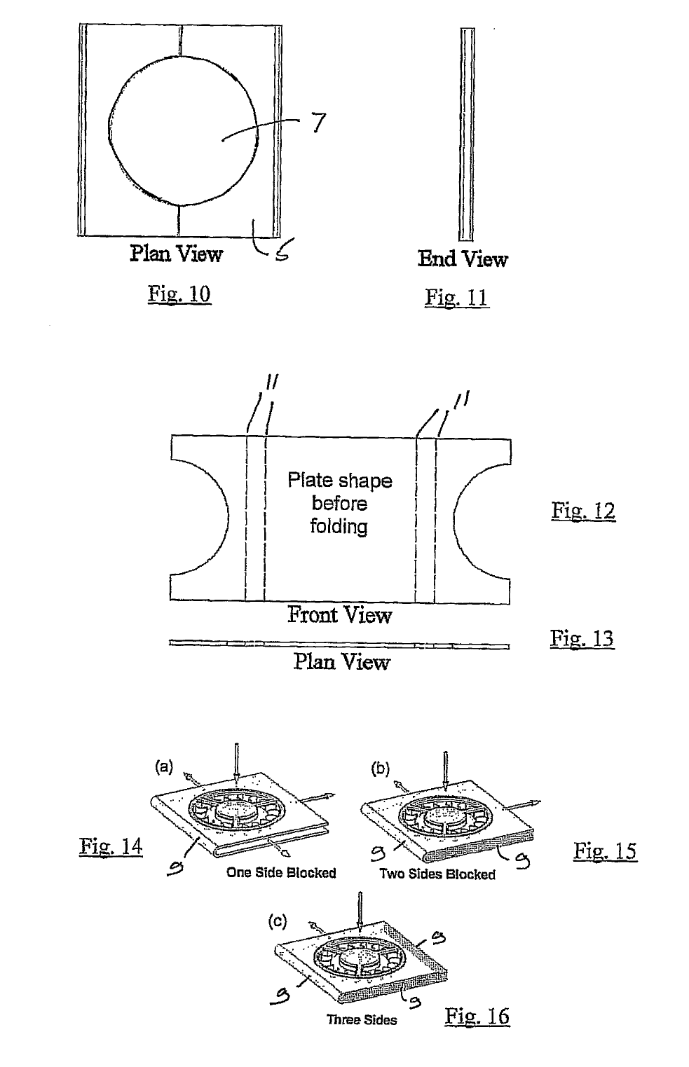

FIGS. 8 to 13 illustrate manufacture of the cooling device 100 of FIG. 1. The dashed lines 11 in FIG. 12 show where the plate is folded to form the heat sink. This arrangement results in good conduction from the base to the upper surface when placed on a chip as the heat path to travel by conduction is reduced.

A heat sink as illustrated in either of the embodiments of FIGS. 1 to 13 is manufactured from a single piece of material and is cheap to manufacture. The heat sink also provides very efficient heat spreading to upper and lower surfaces.

Referring to FIGS. 14 to 15 there are illustrated various cooling devices in which the outlet flow can be directed in three exit directions (FIG. 14 in which there is a single side wall 9), two exit directions (FIG. 15 in which there are two side walls 9), or only one exit direction (FIG. 16 in which there are three side walls 9). The arrows represent direction of airflow, directing the airflow as necessary in some applications.

When the cooling device is approximately square, up to three sides of the heat sink may be blocked without a significant reduction in performance.

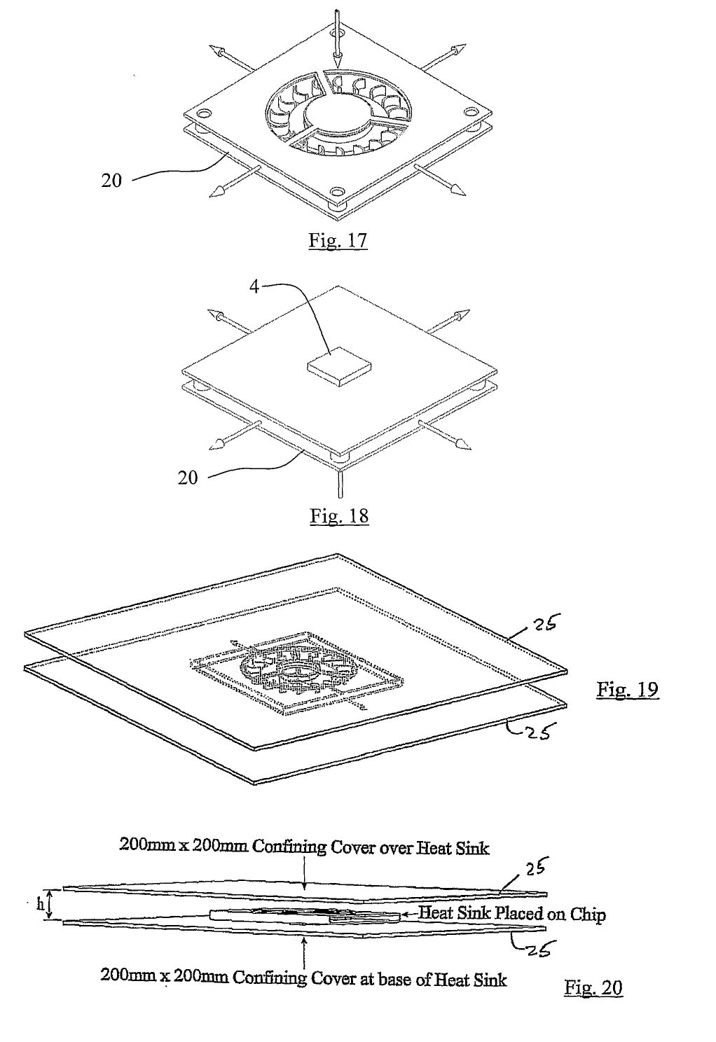

FIGS. 17 and 18 illustrate views of a cooling device in which the top surface, 20, is a non-conducting material. This reduces cost by removing some of the conducting material. This approach results in a minor reduction in performance as the component scale reduces and heat spreading resistance is increased. In this arrangement the surface not in direct contact with the component 4 is a low cost non-conducting material such a plastic material. Arrows represent the direction of airflow.

Any portion of the conducting upper or lower surfaces of the cooling devices described could be replaced by a non-conducting material to balance cost against performance. Some test results of such arrangements are shown in FIG. 55 and described below.

In one embodiment, the cooling device may simply comprise a fan mounted on a single plate where good performance will still be achieved. One such arrangement would be a modification of FIGS. 17 and 18 in which the top plate 20 is removed.

FIGS. 19 and 20 demonstrate application of the cooling devices of the invention in a confined space defined by h, such as the distance between PCB slots in a PC, typically about 17 mm. Because of the low profile nature of the cooling device a significant space exists about the cooling device to draw air from the surroundings. Blockage effects are minimised. FIGS. 19 and 20 show the cooling device in operation where it is confined by simulated nearby walls 25, such as a circuit board or housing of a PC, for example. We have found that the cooling device performs well when placed at least 8 mm from a wall; for spacing less than 8 mm the performance is reduced.

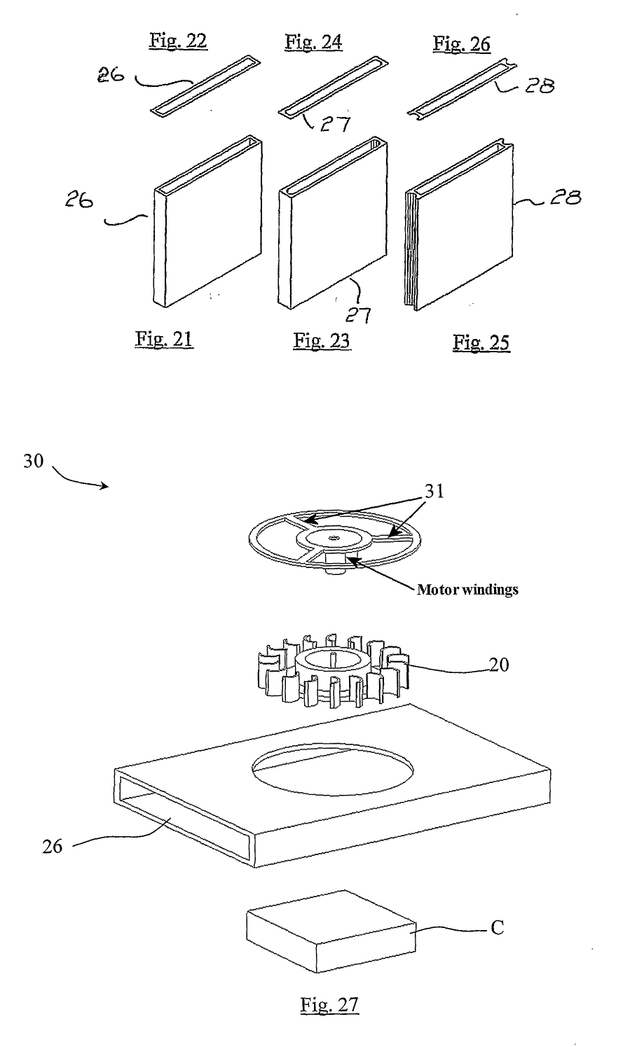

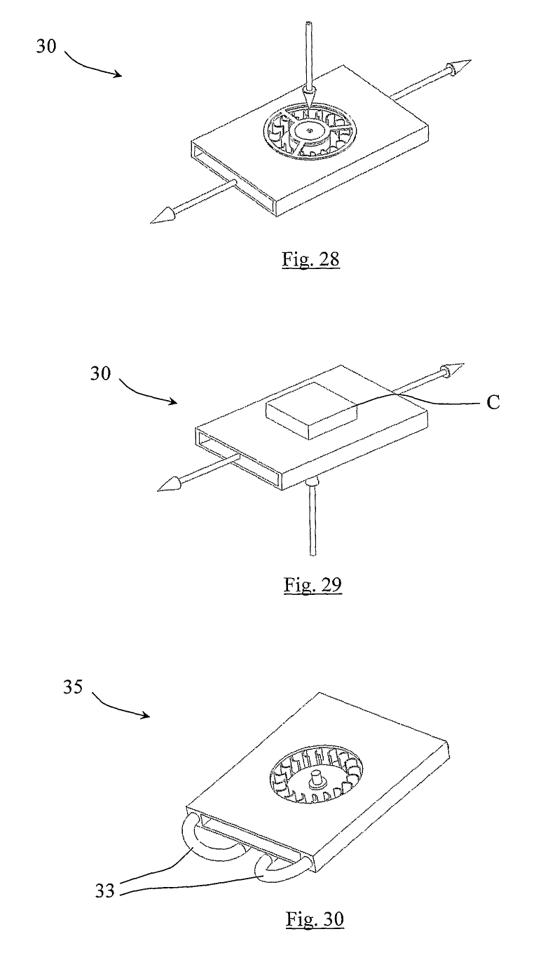

FIGS. 21 to 26 illustrate examples of extruded profiles for a finless heat sink. Material can later be removed from one surface to accommodate the fan and motor assembly. The heat sink may be for direct placement on a heat source (heat sink 26 in FIGS. 21, 22) or attachment to heat source via circular heat pipes (heat sinks 27 and 28 in FIGS. 23, 24, 25, 26) or flattened heat pipes (heat sink 26 in FIGS. 21, 22). The curved surfaces of FIGS. 23 to 26 allow good contact with heat pipes having a circular cross-section.

FIG. 27 shows a cooling device 30 having support struts 31, a fan impeller 32, and the heat sink 26 of FIGS. 21 and 22. FIGS. 28 and 29, show different views of the cooling device 30 in use for cooling a chip C.

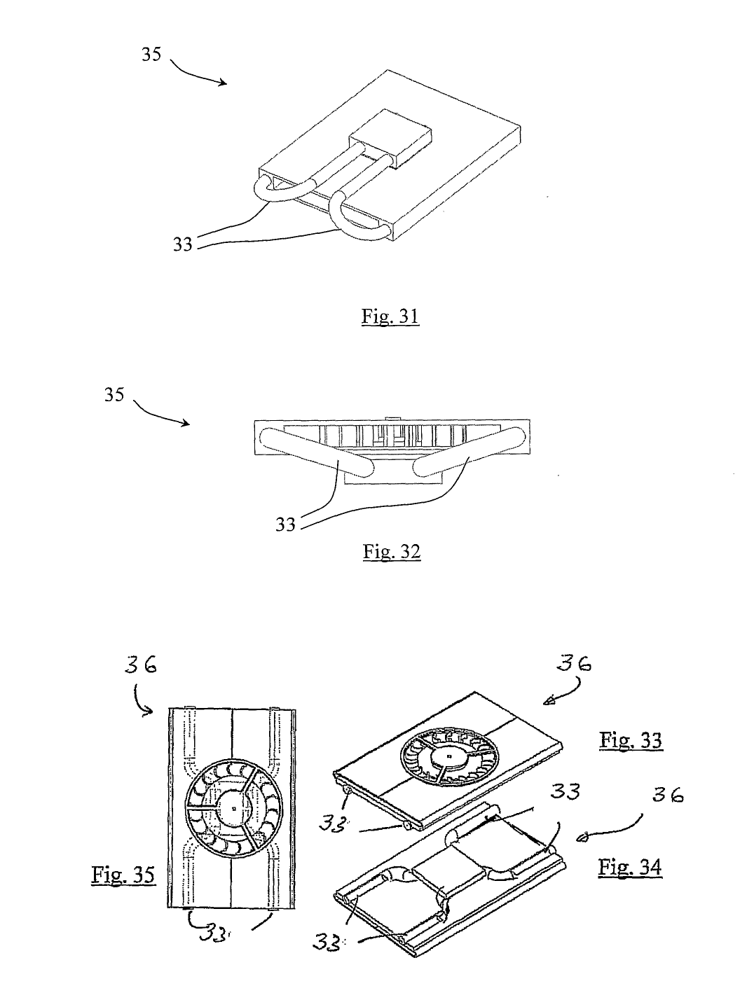

FIGS. 30 to 32 illustrate a cooling device 35 having the extruded or folded finless heat sink of FIG. 27, FIG. 1 or FIG. 2 integrated with heat pipe technology to achieve heat spreading from a small scale component. There is heat transfer both directly through the heat sink and heat transport from the chip to the heat sink via heat pipes 33

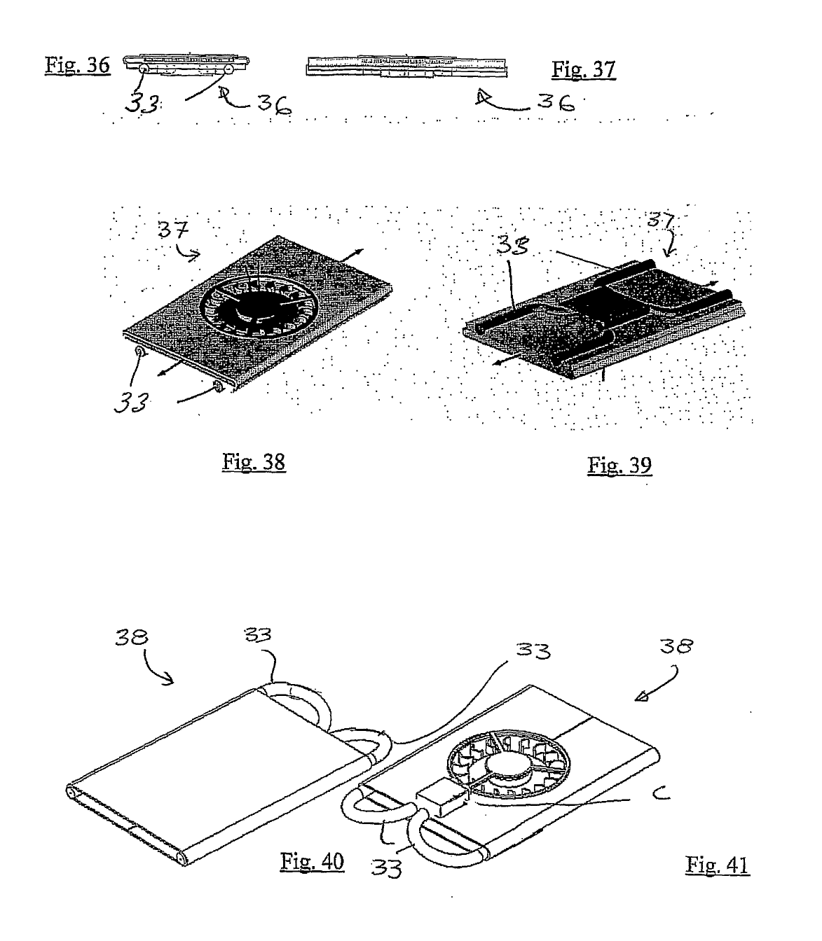

FIGS. 33 to 37 show an alternative cooling device 36 in which heat pipes 33 provide spreading along the base and the heat sink material provides a conduction path to the upper surface. By increasing the number of heat pipes 33, the number of cooling devices as per FIG. 1, 2 or 27 could also be increased in either a lateral or axial direction. FIGS. 38 and 39 show a cooling device, 37, which is similar to the device 36, except in this case the heat sink is extruded instead of being formed from a single piece.

FIGS. 30 to 39 illustrate that cooling devices of the invention can be integrated with heat pipes 33 to achieve low profiles. As illustrated in FIGS. 33 to 39 heat pipes can run in any direction around the cooling device. Heat pipes can run in the same direction as the longest side of the heat sink to minimise the length of heat conduction path as illustrated in FIGS. 30 to 32.

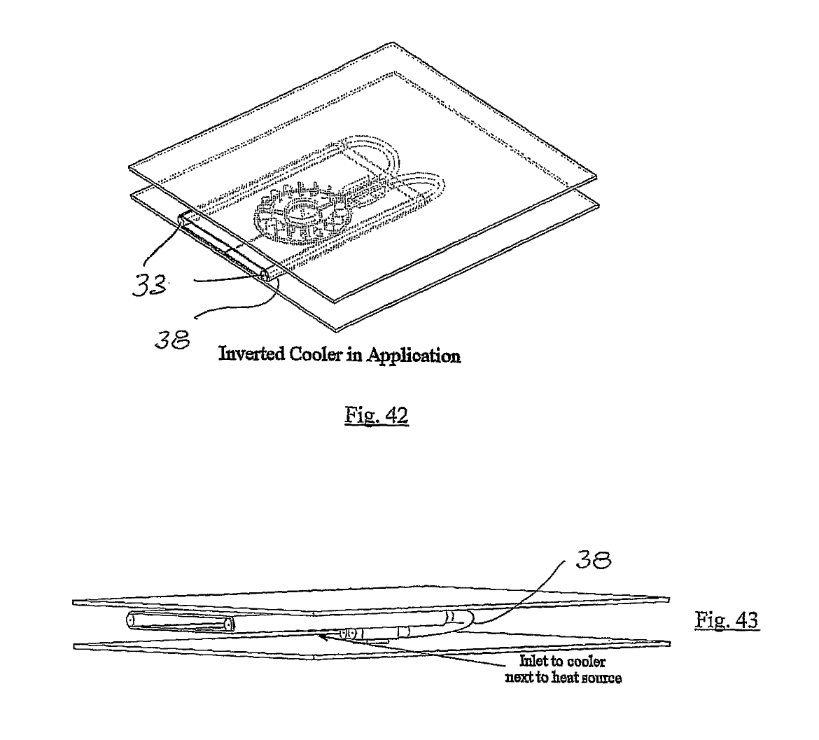

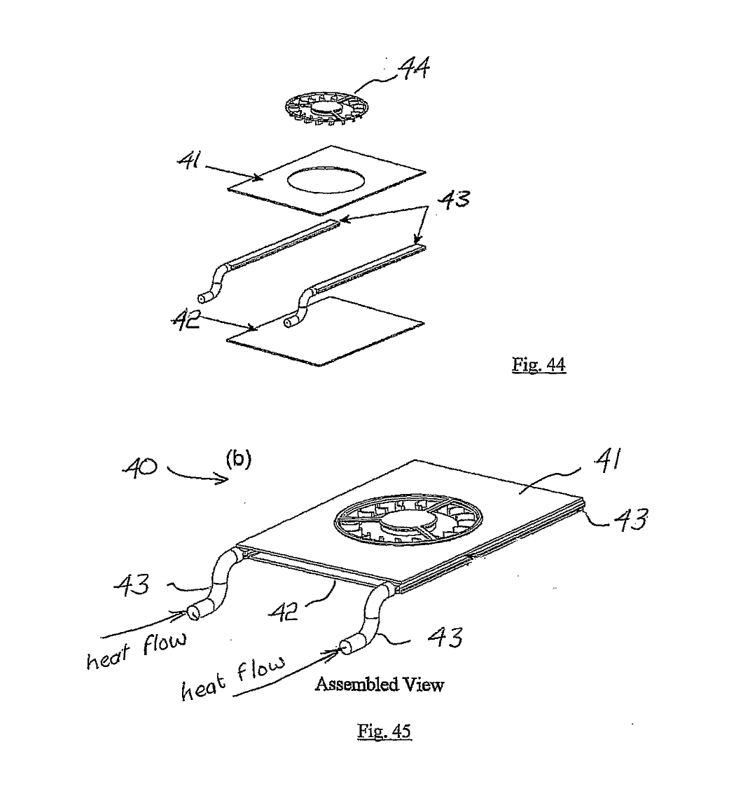

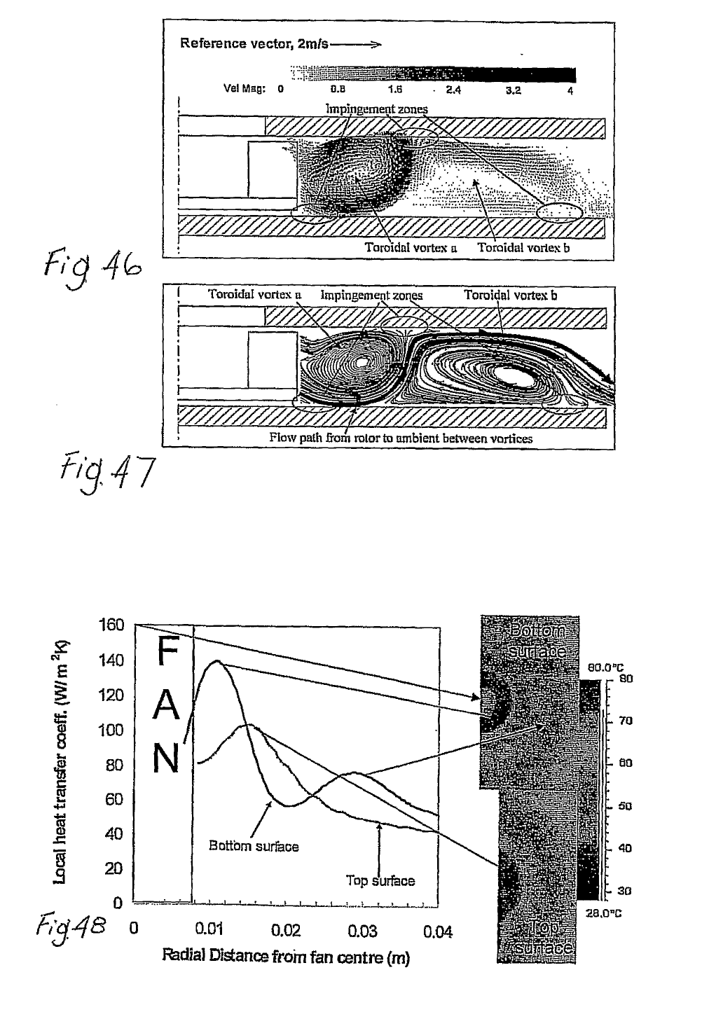

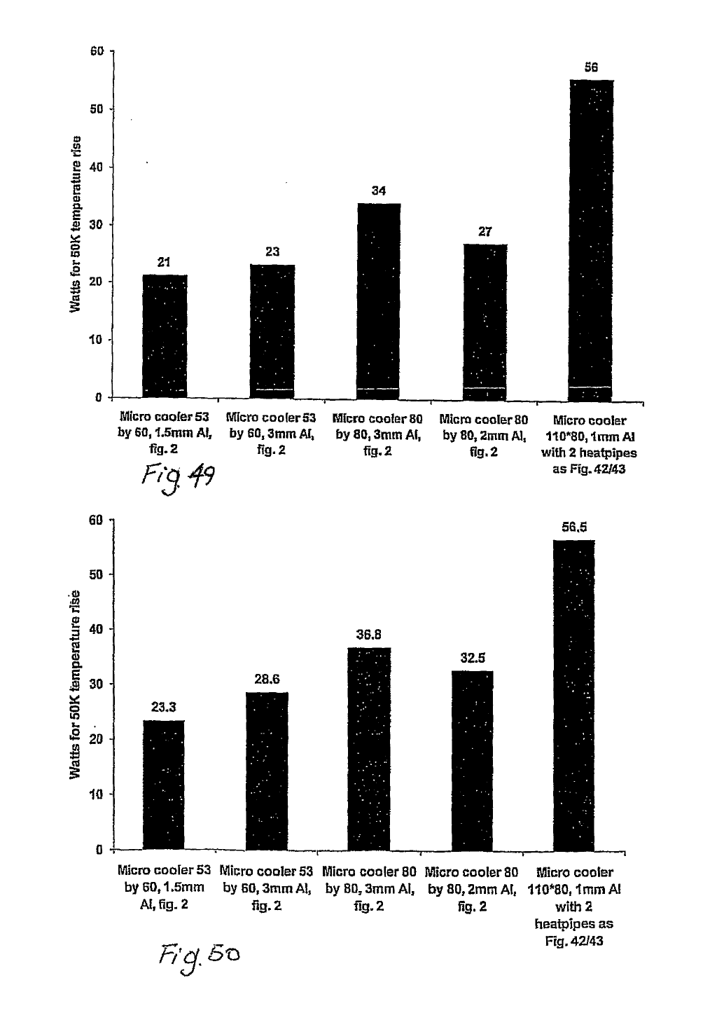

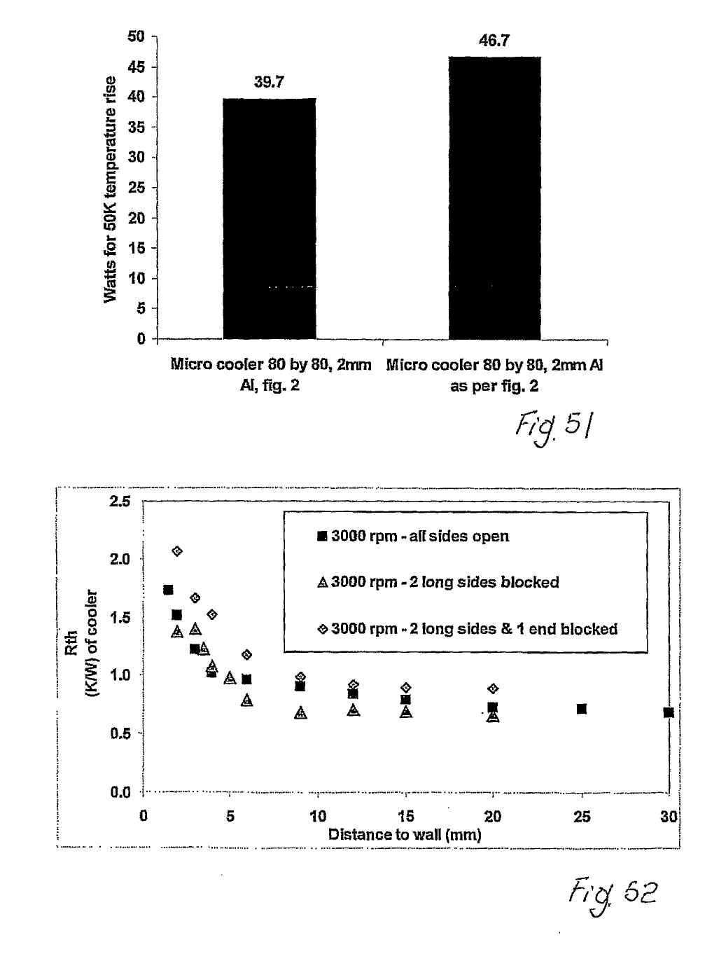

FIGS. 40 and 41 illustrate a cooling device 38 with an inlet from the same side as the chip C to be cooled is placed. FIGS. 42 and 43 illustrate the cooling device 38 in operation in which the air is drawn in at the same side as the chip so that the height between the chip and cooler inlet is greater than in the arrangement of FIGS. 30 to 32 for confined applications with an expected total height of 12-13 mm.

As shown in FIGS. 30 to 39 and in FIGS. 40 to 42, the inlet may be on the side opposite the component C is or on the same side. This allows versatility for use in lower profile, confined, spaces.

Referring now to FIGS. 44 and 45 there is illustrated a cooling device 40 which comprises two separate plates 41 and 42 are attached to flattened heat pipes 43 by soldering for example. A motor and fan assembly 43 is mounted between the plates 41 and 42. This is a cost-effective alternative to use of extruded heat sink elements as shown in FIGS. 21 to 26 since top and bottom surfaces, 41 and 42, can be stamped. In this embodiment, the flattened heat pipes 40 are the heat sink side walls, the heat being transferred via the heat pipes 43 from the chip to the heat dissipating plates 41 and 42.

The use of flat heat pipes and sheets of metal ensures good contact for heat transfer, and use of relatively few parts for manufacture.

The cooling devices of the invention are low profile, capable of operating with a gap between the upper and lower surfaces from about 2 to 5 mm with good performance. Indeed, the gap can be reduced to 1 mm or less.

Heat spreading can be achieved by any solid, single or multiphase technique about the cooling device.

### Test Results

PIV was used as a flow visualisation technique to view the flow field obtained within a finless heat sink manufactured from a single piece of material as shown in FIGS. 2 to 7. The measurements are obtained in the radial-axial planes of FIG. 2.

Images of FIGS. 46 and 47 show measurements from heat sink when vortices are steady between the upper and lower plates, FIG. 46 imaging time averaged velocity vectors, FIG. 47 imaging streamlines of flow field with vortical impingements on upper and lower surfaces noted.

As the rotor velocity and size increases in all the folded finless designs the vortex flow in the cavity formed by the folded heat sink becomes unsteady in nature. Results from the same plane as FIG. 46 from a cooler as shown in FIG. 2 are shown for a 38 mm rotor at 6000 RPM. The cooling device was enclosed by a wall of 200 mm squared above and below (as shown in FIGS. 19 and 20), with a h dimension of 16 mm. Both instantaneous and averaged flow fields (bottom right) are shown to illustrate the unsteady nature of the vortices. In some instants in time the vortices do not appear to exist from the instantaneous images, although it is the unsteady nature of the flow between the time averaged and instantaneous flow field which ultimately drives good heat transfer rates.

In the PIV measurement results of FIGS. 46 and 47, it is noted that the vortices provide impingement zones on the upper and lower surfaces and also create unsteadiness in the flow field. FIG. 48 shows the resultant local heat transfer coefficient measurements obtained from Infra red thermography using a 12.5 m² stainless steel foil as the heat sink base and upper surfaces. The image on the right shows the resultant thermal map from a constant heat flux boundary condition on the bottom plate, the fan is located at the centre of the image. This image is then averaged to provide a direct measure of local heat transfer coefficient on the left hand side for the upper and lower surfaces. The graph of FIG. 48 represents the local heat transfer coefficient from the centre of the fan along a radial line to the end of the upper and lower surfaces; the location of the fan blades is marked for clarity. The existence of two peaks in heat transfer coefficient will be noted which correspond to the impingement regions on the lower surface found from the PIV images of FIGS. 46 and 47, and the same for the upper surface where one impingement zone was identified from the PIV measurements of FIGS. 46 and 47. As the rotor diameter and speed is increased the location of these peaks moves back closer to fan blades and eventually between the fan blades.

FIG. 48: Local heat transfer coefficient calculated from Infra-red thermal map shown on right for lower surface only. The impingement regions agree with the peaks found in the local heat transfer coefficient as marked by arrows for the lower surface of the cooling device. The upper surface of the cooling device also shows a rise in heat transfer with the impingement region on the upper surface.

### EXAMPLES

In some examples, the following heat sinks were manufactured:
A: 80 mm by 80 mm footprint area, with 3.5-4 mm spacing between upper and lower plates from 2 mm thick Al and 3 mm thick Al sheets, as shown in FIG. 2
B: 53 mm by 60 mm footprint area, and 3.5-4 mm spacing from 1.5 mm thick Al and 3 mm thick Al, as shown in FIG. 2
C: 110 mm by 80 mm footprint area, with 3.5-4 mm spacing between upper and lower plates from 1 mm thick Al, integrated with heat pipes as shown in FIGS. 40 to 41.

The heat sinks A, B, C were tested with a height constraint between two walls of 16 mm and 34 mm between the confining plates as illustrated in FIGS. 19 and 20, as typical of computing systems. The tests were carried out using two packages of 12 mm squared and 32 mm squared where the package surface temperature was record by embedding thermocouples with rotational speeds of around 4300 RPM.

The result of power dissipation achieved for a 50 degree Kelvin temperature rise is shown in FIGS. 49, 50 and 51 for a 12 mm chip with a cover plate 12.7 and 34.8 mm above the base of the chip and a 32 mm chip with the cover 12.7 and 34.8 mm above the base respectively. A thermal interface material (Dow Corning Thermal Compound 340) was used.

FIG. 49: Tests with manufactured heat sinks in setup shown in FIGS. 19 and 20, with a h of 16 mm, and cooling devices placed on a 12 mm squared component.

FIG. 50: Tests with manufactured heat sinks in setup shown in FIGS. 19 and 20, with a h of 34 mm, and cooling devices placed on a 12 mm squared component.

FIG. 51: Tests with manufactured heat sinks in setup shown in FIGS. 19 and 20, with a h of 16 mm (left column) and 34 mm (right column), and cooling devices placed on a 32 mm squared component.

FIG. 52 shows the effect of blocking the exits of multiple sides of the heat sink and the distance between the inlet and another solid plate. For this scale, as long as any blockage plate (e.g. graphics card slot) at the inlet is beyond 6-8 mm the performance is similar to that obtained with no blockage.

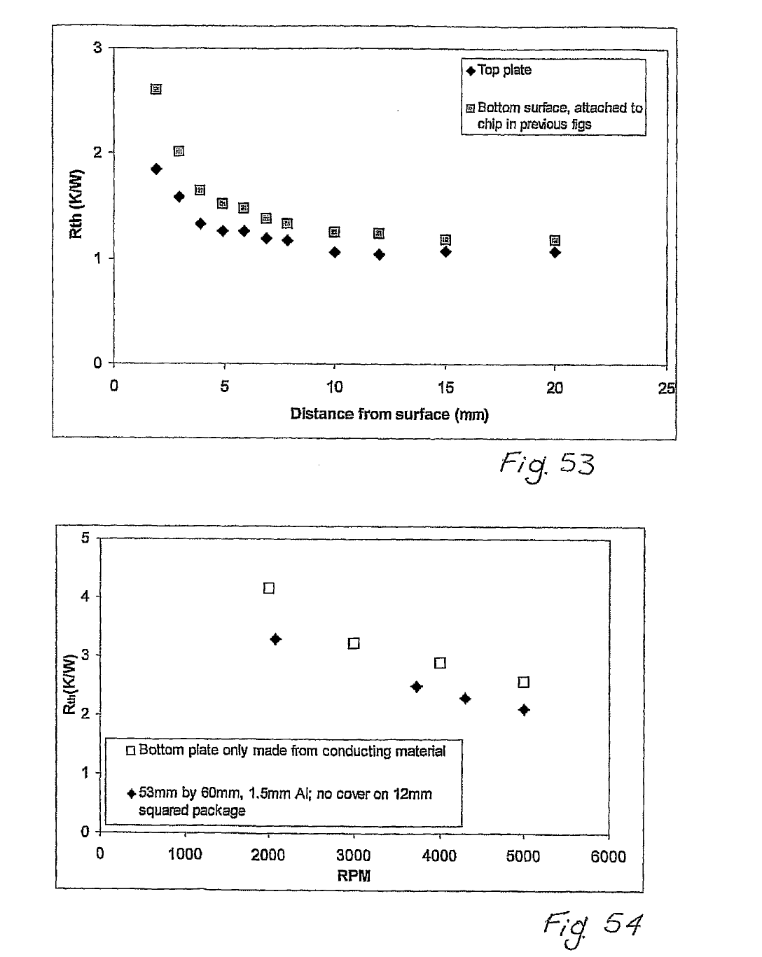

FIG. 53 shows the thermal resistance of the upper and lower plate independently for the case of blockage at inlet as per FIG. 52 which shows the averaged performance of the upper and lower plates of the device.

FIG. 54 shows the performance of the device when the upper plate is made from a non-conducting material and the base plate is in contact with the chip surface.

FIG. 55 shows the performance when a percentage of the upper plate is made from a non conducting material (plastics).

The weight of the cooling device is proportional to the cost, the relative weight of the device is shown below in Table 1.

TABLE 1

| Heat sink description | Weight (Grams) |
|---|---|
| 110 by 85 mm, 1 mm A1, with heat pipes, FIG. 40 | 160 |
| 80 by 80 mm, 3 mm A1, FIG. 2 | 102 |
| 80 by 80 mm, 2 mm A1, FIG. 2 | 75 |
| 53*60 mm, 3 mm A1, FIG. 2 | 54 |
| 53*60 mm, 1.5 mm A1, FIG. 2 | 32 |
| 50*50 mm, 1 mm A1, FIG. 2 | 16 |

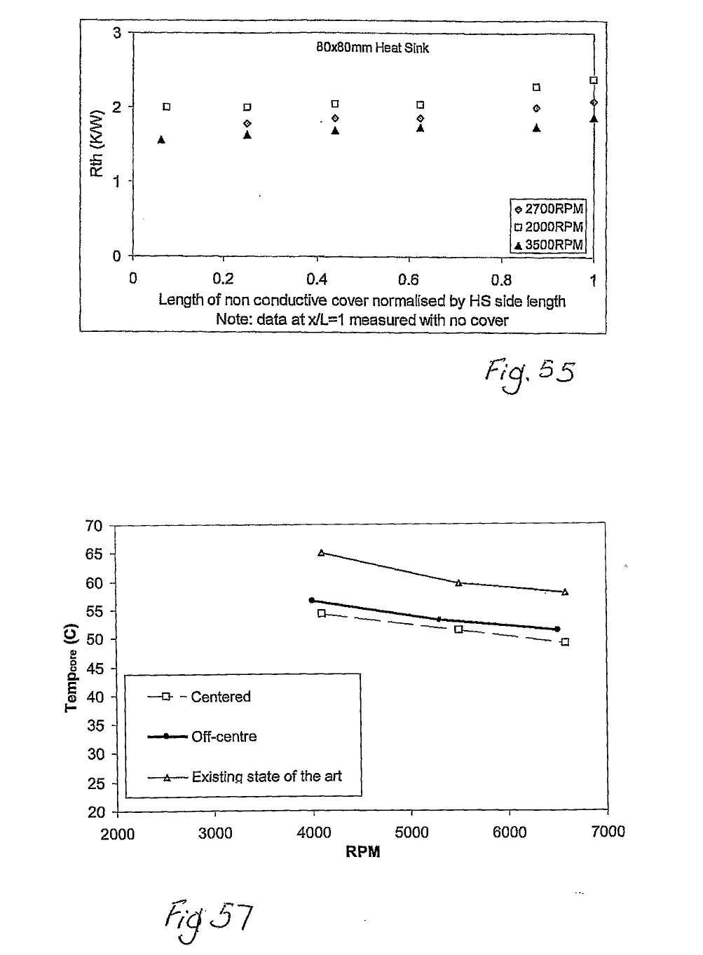

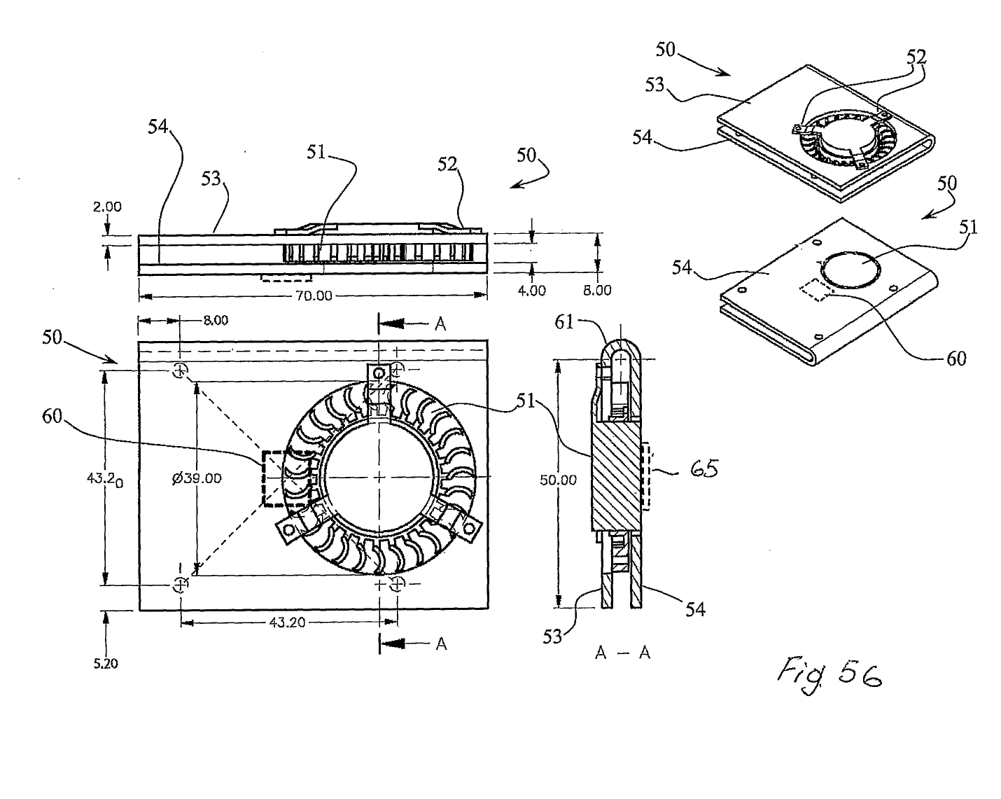

Referring to FIGS. 56 and 57 another cooling device, 50, of the invention comprises a fan 51 supported by radial supports 52, a top plate 53, a bottom plate 54, and a side wall 61. The motor of the fan 51 extends through both of the plates 53 and 54, extending proud of the top plate 53 and being flush with the outer surface of the bottom plate 54. It does not have to extend proud of the top plate or be flush with the bottom plate. A thinner motor could be lower than the top plate, or only partly extend into the base plate, or could also extend beyond the base plate.

Thus the fan 51 does not need to be confined in size in the axial direction to the internal separation of the plates. It uses the thicknesses of the top and bottom plates 53 and 54 (2 mm each in this case) plus the additional amount to which it protrudes from the top plate. In another embodiment the fan does not protrude from either plate, merely extending through the thickness of each plate and being flush with the outside surfaces.

It will be noted that the fan 51 is located offset as viewed in plan. This is to allow a significant surface area to the side of the fan 51 for contact of the device 50 with the circuit being cooled, and allows the motor to protrude through the bottom plate, if desired. The dotted rectangle 60 indicates the location of the circuit being cooled in one embodiment. This is advantageous as it is over a volume encompassing both the blades of the fan 51 and vortex circulation of air. The location 60 is a good compromise between convenient mounting of the circuit and the device 50, and optimum heat transfer. However, if the mounting and space allowed it, there would be even better heat transfer if the circuit were located close to approximately 90° closer to the top as viewed in plan. This would be closer to a side wall 61 and so achieving a shorter heat transfer path to the top plate 54.

In mounting the device 50 any protruding parts of the circuit 60 would be located directly beneath the fan 51, as shown by the dotted 65 line in FIG. 56. An example circuit is a graphics processing unit, GPU.

FIG. 57 demonstrates the variation in performance when the motor is off centred as shown in FIG. 56, relative to when the motor is centred as shown in FIG. 1. It shows temperatures for various fan speeds. The square dots are for the results with the circuit located at 60 as shown in FIG. 56, the round dots for an off-centre location closer to the side wall, and the triangular dots for a conventional cooling device currently employed on single slot graphics processing units. In general, the most effective arrangement is when the bottom plate has no orifice in it and the motor is suspended from the top surface as in earlier drawings.

It will be appreciated that the invention provides methods of manufacturing cooling devices which allow inexpensive manufacturing both in terms of materials and assembly time and complexity. Also, the invention provides cooling devices which are compact and very efficient at removing heat from heat sources, particularly where space is very confined.

The invention is not limited to the embodiments hereinbefore described, which may be varied in detail. For example the heat sink may in some embodiments have a curved shaped in plan, with only part of the circumference having a wall.

1-38. (canceled)

39. A cooling device comprising:—
a fluid pump having a cooling device inlet;
a heat sink comprising axially spaced-apart opposed heat transfer surfaces and a side wall means connecting the surfaces;
the heat sink having a cooling device outlet on a side thereof.

40. The cooling device as claimed in claim 39, wherein the side wall means does not extend fully around the perimeter of the heat sink.

41. The cooling device as claimed in claim 39, wherein the heat sink comprises a plurality of sides and the cooling device outlet is provided on at least one of the sides.

42. The cooling device as claimed in claim 39, wherein the heat sink comprises a plurality of sides and the cooling device outlet is provided on at least one of the sides; and wherein the heat sink comprises four sides and the cooling device outlet is provided on at least one of the sides.

43. The cooling device as claimed in claim 39, wherein the heat sink comprises a plurality of sides and the cooling device outlet is provided on at least one of the sides; and wherein the heat sink comprises four sides and the cooling device outlet is provided on at least one of the sides; wherein the cooling device outlet is provided on one side, and side wall means are provided on the other three sides.

44. The cooling device as claimed in claim 39, wherein the heat sink comprises a plurality of sides and the cooling device outlet is provided on at least one of the sides; and wherein the heat sink comprises four sides and the cooling device outlet is provided on at least one of the sides; wherein the cooling device outlet is provided on one side, and side wall means are provided on the other three sides; and wherein the cooling device outlet is provided on two opposite sides and side walls are provided on the other two sides.

45. The cooling device as claimed in claim 39, wherein the heat sink is approximately square-shaped in plan view.

46. The cooling device as claimed in claim 39, wherein the heat sink is approximately square-shaped in plan view; and wherein the spaced-apart opposed surfaces of the heat sink define a volume without heat dissipating fins extending from the heat sink inlet facing the pump.

47. The cooling device as claimed in claim 39, wherein the cooling device outlet is on a side opposed to the heat sink inlet in the radial direction.

48. The cooling device as claimed in claim 39, wherein the surfaces are substantially parallel, and the fluid pump comprises rotor impellers having a diameter in the range of 0.7 to 0.8 times width of the heat sink.

49. The cooling device as claimed in claim 39, wherein the heat sink comprises at least two plates which are interconnected by the side wall means.

50. The cooling device as claimed in claim 39, wherein the heat sink comprises at least two plates which are interconnected by the side wall means; and wherein a plate has an aperture providing the cooling device inlet.

51. The cooling device as claimed in claim 39, wherein the heat sink comprises at least two plates which are interconnected by the side wall means; and wherein both plates comprise a heat conducting material.

52. The cooling device as claimed in claim 39, wherein the heat sink comprises at least two plates which are interconnected by the side wall means; and wherein both plates comprise a heat conducting material; and wherein the heat sink comprises a single piece of material.

53. The cooling device as claimed in claim 39, wherein the heat sink comprises at least two plates which are interconnected by the side wall means; and wherein both plates comprise a heat conducting material; and wherein the heat sink comprises a single piece of material; and wherein the material is shaped to provide the heat sink.

54. The cooling device as claimed in claim 39, wherein the heat sink comprises at least two plates which are interconnected by the side wall means; and wherein both plates comprise a heat conducting material; and wherein the heat sink comprises a single piece of material; and wherein the heat sink is of moulded construction.

55. The cooling device as claimed in claim 39, wherein the heat sink comprises an extrusion.

56. The cooling device as claimed in claim 39, wherein the heat sink is formed by folding.

57. The cooling device as claimed in claim 39, wherein the heat sink is formed by folding; and wherein the heat sink is generally U-shaped in transverse cross section.

58. The cooling device as claimed in claim 39, wherein only a single plate comprises a heat conducting material.

59. The cooling device as claimed in claim 39, further comprising a heat spreading means.

60. The cooling device as claimed in claim 39, further comprising a heat spreading means; and wherein the heat spreading means comprises heat pipe means.

61. The cooling device as claimed in claim 39, further comprising a heat spreading means; and wherein the heat spreading means comprises heat pipe means; and wherein the heat pipe means is flattened to provide enhanced heat transfer between the pipe and a heat transfer surface of the heat sink.

62. The cooling device as claimed in claim 39, wherein the gap between opposed surfaces of the heat sink is less than 5 mm.

63. A cooling device comprising:—
a heat sink comprising a single plate having a heat conducting surface, the heat conducting surface being in contact with an article to be cooled or separated therefrom by a thermal interface material; and
a fluid pump adjacent to the conducting surface.

64. A cooling device comprising:—
a fluid pump having a cooling device inlet;
a heat sink comprising axially spaced-apart opposed surfaces;
the heat sink having a cooling device outlet on a side thereof, wherein the heat sink comprises both heat conducting and non heat conducting materials.

65. The cooling device as claimed in claim 63 wherein the heat sink comprises at least two plates which are spaced-apart in the axial direction, at least one of the plates being at least partially of a non heat-conducting material.

66. The cooling device as claimed in claim 39, wherein the heat sink comprises at least two plates which are interconnected by the side wall means; and wherein the fluid pump extends through a plate.

67. The cooling device as claimed in claim 39, wherein the heat sink comprises at least two plates which are interconnected by the side wall means; and wherein the fluid pump extends through a plate; and wherein the fluid pump extends through both plates.

68. The cooling device as claimed in claim 39, wherein the heat sink comprises at least two plates which are interconnected by the side wall means; and wherein the fluid pump extends through a plate; and wherein the fluid pump protrudes from an external surface of at least one plate.

69. The cooling device as claimed in claim 39, wherein the heat sink comprises at least two plates which are interconnected by the side wall means; and wherein the fluid pump is located offset with respect to the centre of the plates as viewed in plan, providing a contact area to a side of the pump for contact with a device to be cooled.

70. A cooling device comprising:—
a fluid pump having a cooling device inlet; and
a heat sink comprising axially spaced-apart opposed surfaces wherein the gap between the opposed surfaces of the heat sink is less than 5 mm.

71. An electronic circuit assembly comprising a cooling device as claimed in claim 39, and an electronic circuit in contact with the cooling device.

72. The electronic circuit assembly as claimed in claim 70, wherein the fluid pump comprises impeller blades and the circuit contacts the cooling device at a location aligned with the blades of the pump and a volume immediately radially beyond the blades.

73. The electrical circuit assembly as claimed in claim 70, wherein the fluid pump comprises impeller blades and the circuit contacts the cooling device at a location aligned with the blades of the pump and a volume immediately radially beyond the blades; and wherein the location is adjacent to a side wall interconnecting the surfaces.

74. An electronic heat dissipating device comprising an electrical circuit assembly as claimed in claim 70.

75. The electrical heat dissipating device as claimed in claim 73, wherein the device is portable.
